(19) United States
(12) Patent Application Publication
(10) Pub. No.: US 2010/0207196 A1
(43) Pub. Date: Aug. 19, 2010

(54) SEMICONDUCTOR DEVICE HAVING INTERNAL GATE STRUCTURE AND METHOD FOR MANUFACTURING THE SAME

(76) Inventors: Min Jung SHIN, Gyeonggi-do (KR); Seong Hwan KIM, Seoul (KR)

Correspondence Address: LADAS & PARRY LLP, 224 SOUTH MICHIGAN AVENUE, SUITE 1600, CHICAGO, IL, 60604, US

(21) Appl. No.: 12/411,536

(22) Filed: Mar. 26, 2009

(30) Foreign Application Priority Data
Feb. 16, 2009 (KR) 10-2009-0012419

(51) Int. Cl. H01L 29/78; H01L 21/336

(52) U.S. Cl. 257/327; 438/283; 257/E29.255; 257/E21.421

(57) ABSTRACT

A semiconductor device includes a main gate formed on a semiconductor substrate and a source region and a drain region formed in a surface of the semiconductor substrate on opposite sides of the main gate. An internal gate formed within a portion of the main gate that adjoins the source region.

### CROSS-REFERENCE TO RELATED APPLICATIONS

The present application claims priority to Korean patent application number 10-2009-0012419 filed on Feb. 16, 2009, which is incorporated herein by reference in its entirety.

### BACKGROUND OF THE INVENTION

The present invention relates generally to a semiconductor device and a method for manufacturing the same, and more particularly, to a semiconductor device having a structure capable of preventing a drain-induced barrier lowering (DIBL) phenomenon without undergoing a gate-induced drain leakage (GIDL) phenomenon, thereby improving the characteristics and the reliability of a semiconductor device, and a method for manufacturing the same.

As the level of integration of a semiconductor device increases the channel length of a transistor decreases. The decrease in the channel length results in an increase in the occurrence of a charge sharing phenomenon between a source region and a drain region. and a decrease in the controllability of a gate. That is, a short channel effect, in which a threshold voltage abruptly decreases, is caused. Also, as the channel length decreases, a DIBL phenomenon occurs thereby deteriorating the characteristics and the reliability of a semiconductor device.

In detail, according to the DIBL phenomenon, when a voltage is applied to a drain region with a gate turned off, the depletion layer of the drain region interacts with a source region due to a short channel length, and a difference in potential barrier between the source region and a channel decreases. If the DIBL phenomenon occurs, the characteristics and the reliability of a semiconductor device deteriorate because leakage current increases.

The DIBL phenomenon is increasingly problematic as the channel length gradually decreases in pace with the trend toward higher integration of a semiconductor device. Under these situations, methods for preventing the DIBL phenomenon, and thereby improving the characteristics and the reliability of a semiconductor device, have been examined.

A method of applying a negative voltage to a gate to prevent the DIBL phenomenon has been proposed in the art. In this method, even when a voltage is applied to a drain region with a gate turned off, since a difference in potential barrier between a source region and a channel can be secured to some extent, the DIBL phenomenon is prevented, and leakage current can be decreased.

However, in this conventional method, as the negative voltage is applied to the gate, the difference in voltage between the gate and the drain region increases, this results in an occurrence of a GIDL phenomenon. Due to this fact, leakage current increases, and the characteristics and the reliability of the semiconductor device deteriorate as well. Consequently, in the conventional method of applying the negative voltage to the gate, while the DIBL phenomenon due to the decrease in the channel length can be prevented to some extent, the GIDL phenomenon is caused due to the difference in voltage between the gate and the drain region, whereby the problem by the increase in leakage current is not solved. Therefore, a method for preventing the DIBL phenomenon without undergoing the GIDL phenomenon and thereby effectively decreasing leakage current is demanded in the art.

### SUMMARY OF THE INVENTION

Embodiments of the present invention include a semiconductor device capable of preventing a DIBL phenomenon without undergoing a GIDL phenomenon, thereby reducing current leakage, and a method for manufacturing the same.

Also, embodiments of the present invention include a semiconductor device capable of improving the characteristics and the reliability of a semiconductor device and a method for manufacturing the same.

In one aspect of the present invention, a semiconductor device comprises a main gate formed on a semiconductor substrate; a source region and a drain region formed in a surface of the semiconductor substrate on both sides, respectively, of the main gate; and an internal gate formed in a portion of the main gate which adjoins the source region.

The internal gate has spacers on both sidewalls thereof.

The internal gate is formed such that one side end of the internal gate which adjoins the source region is flush with one side end of the main gate which adjoins the source region.

The semiconductor device further comprises first contacts formed to contact the main gate; and a second contact formed to contact the internal gate.

In another aspect of the present invention, a method for manufacturing a semiconductor device comprises the steps of forming a main gate on a semiconductor substrate and an internal gate in a portion of the main gate; and forming a source region in a surface of a portion of the semiconductor substrate which adjoins the portion of the main gate in which the internal gate is formed and a drain region in a surface of another portion of the semiconductor substrate which adjoins the other side end of the main gate.

The internal gate is formed such that it has spacers on both sidewalls thereof.

The internal gate is formed such that one side end of the internal gate which adjoins the source region is flush with one side end of the main gate which adjoins the source region.

After the step of forming the source region and the drain region, the method further comprises the step of forming first contacts which contact the main gate and a second contact which contacts the internal gate.

In still another aspect of the present invention, a method for manufacturing a semiconductor device comprises the steps of forming a conductive pattern on a semiconductor substrate; forming a conductive layer on the semiconductor substrate formed lo with the conductive pattern, to cover the conductive pattern; forming a main gate by etching the conductive layer and an internal gate in a portion of the main gate by etching the conductive pattern; and forming a source region in a surface of a portion of the semiconductor substrate which adjoins the portion of the main gate in which the internal gate is formed and a drain region in a surface of another portion of the semiconductor substrate which adjoins the other side end of the main gate.

The step of forming the conductive pattern comprises the steps of forming a first gate insulation layer, a first gate conductive layer, and a first gate hard mask layer on the semiconductor substrate; and etching the first gate hard mask layer, the first gate conductive layer, and the first gate insulation layer.

After the step of forming the conductive pattern and before the step of forming the conductive layer, the method further comprises the step of forming spacers on both sidewalls of the conductive pattern.

After the step of forming the conductive pattern and before the step of forming the conductive layer, the method further comprises the step of forming a second gate insulation layer for a main gate on the semiconductor substrate which is formed with the conductive pattern.

The conductive layer comprises a second gate conductive layer for a main gate.

After the step of forming the conductive layer and before the step of forming the main gate and the internal gate, the method further comprises the steps of conducting a planarization process for the conductive layer; and forming a second hard mask layer for a main gate on the conductive layer for which the planarization process is conducted.

The step of forming the main gate and the internal gate comprises the steps of forming a mask pattern on the conductive layer to overlap with one side end portion of the conductive pattern; etching the conductive layer and the conductive pattern using the mask pattern as an etch mask; and removing the mask pattern.

The internal gate is formed such that one side end of the internal gate which adjoins the source region is flush with one side end of the main gate which adjoins the source region.

After the step of forming the source region and the drain region, the method further comprises the step of forming first contacts which contact the main gate and a second contact which contacts the internal gate.

### BRIEF DESCRIPTION OF THE DRAWINGS

FIG. 1 is a plan view showing a semiconductor device in accordance with an embodiment of the present invention.

FIG. 2 is a cross-sectional view taken along the line A-A′ of FIG. 1, showing the semiconductor device in accordance with an embodiment of the present invention.

FIGS. 3A through 3G are cross-sectional views taken in correspondence with the line A-A′ of FIG. 1, shown for illustrating the processes of a method for manufacturing a semiconductor device in accordance with another embodiment of the present invention.

### DESCRIPTION OF SPECIFIC EMBODIMENTS

In the present invention, a main gate is formed on a semiconductor substrate, and an internal gate is formed within a portion of the main gate that adjoins a source region. When the main gate is turned off, a negative voltage is selectively applied to the internal gate, which adjoins the source region. Since the negative voltage is selectively applied to the internal gate which adjoins the source region, a difference in potential barrier between the source region and a channel is prevented from decreasing, while a difference in voltage between the main gate and a drain region is prevented from increasing. As a consequence, in the present invention, a DIBL phenomenon is prevented from occurring without undergoing a GIDL phenomenon.

Hereafter, specific embodiments of the present invention will be described with reference to the accompanying drawings.

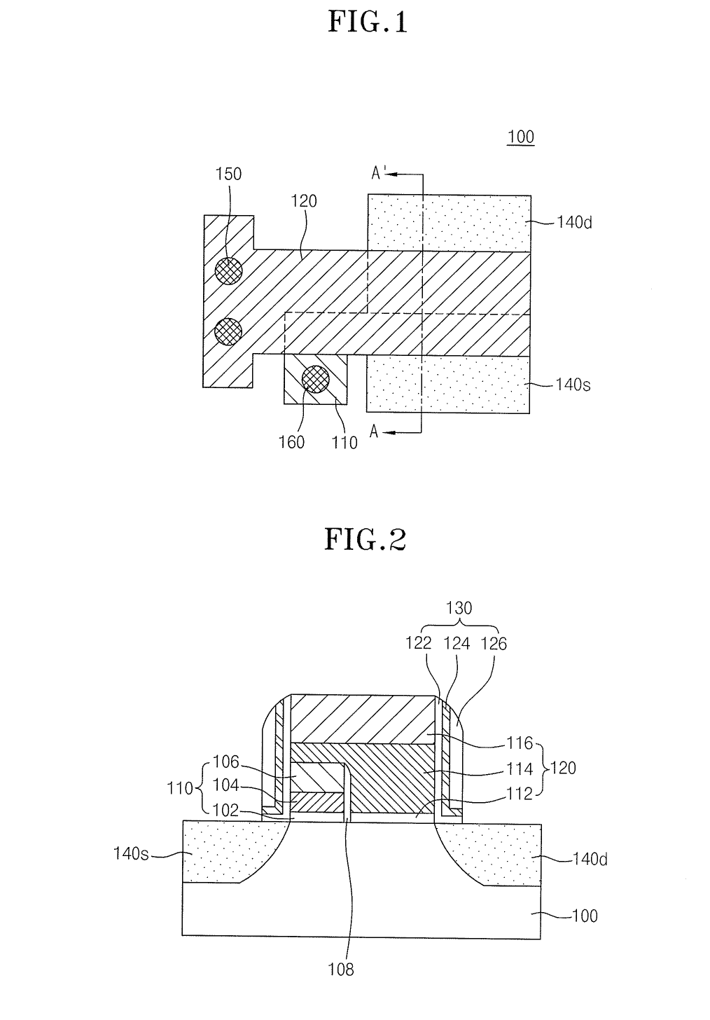

FIG. 1 is a plan view showing a semiconductor device in accordance with an embodiment of the present invention, and FIG. 2 is a cross-sectional view taken along the line A-A′ of FIG. 1, showing the semiconductor device in accordance with an embodiment of the present invention.

Referring to FIGS. 1 and 2, a semiconductor device in accordance with an embodiment of the present invention includes a main gate 120 formed on a semiconductor substrate 100, a source region 140s and a drain region 140d formed in the surface of the semiconductor substrate 100 on both sides, respectively, of the main gate 120, and an internal gate 110 formed within a portion of the main gate 120 adjoining the source region 140s. Preferably, the internal gate 110 is formed such that one side end of the internal gate 110 adjoining the source region 140s is flush (i.e., substantially coplanar) with one side end of the main gate 120 adjoining the source region 140s.

As shown in FIG. 2, according to an embodiment of the present invention the internal gate 110 has a stack structure of a first gate insulation layer 102, a first gate conductive layer 104, and a first gate hard mask layer 106. First spacers 108 are formed on a sidewall of the internal gate 110. The first spacers 108 are composed of, for example, the stack of an oxide layer and a nitride layer.

The main gate 120 has a stack structure of a second gate insulation layer 112, a second gate conductive layer 114, and a 1o second gate hard mask layer 116. Second spacers 130 are formed on both sidewalls of the main gate 120. The second spacers 130 are composed of, for example, the stack of a first oxide layer 122, a nitride layer 124, and a second oxide layer 126. As shown in FIG. 1, according to an embodiment of the present invention first contacts 150 are formed on the main gate 120 so as to contact the main gate 120, and a second contact 160 is formed on the internal gate 110 so as to contact the internal gate 110.

In the embodiment of the present invention, different voltages can be applied to the main gate 120 and the internal gate 110 through the first contacts 150 and the second contact 160, respectively. In detail, when the main gate 120 is turned off, a Vss voltage is applied to the main gate 120 through the first contacts 150, a negative voltage is selectively applied to the internal gate 110 adjoining the source region 140s through the second contact 160, a Vss voltage is applied to the source region 140s, and a Vdd voltage is applied to the drain region 140d.

As described above, if a voltage is applied to a drain region of a semiconductor device when a gate is turned off, the depletion layer of the drain region interacts with the source region 140s due to the short channel length, and a difference in potential barrier between a source region and a channel of the semiconductor device decreases, whereby a DIBL phenomenon occurs. According to the embodiment of the present invention, due to the fact that the negative voltage is selectively applied to the internal gate 110 adjoining the source region 140s, the difference in potential barrier between the source region 140s and the channel can be sufficiently secured. Therefore, in the present invention, the DIBL phenomenon can be prevented, and leakage current can be decreased due to the application of the negative voltage to the internal gate 110.

In the embodiment of the present invention, since the negative voltage is not applied to the entire main gate 120 and instead, is selectively applied to the internal gate 110 adjoining the source region 140s, the difference in voltage between the main gate 120 and the drain region 140d is decreased. Thus, in the present invention, the DIBL phenomenon is prevented without undergoing the GIDL phenomenon. Therefore, in the present invention, because the DIBL phenomenon can be effectively prevented without undergoing the GIDL phenomenon, leakage current can be decreased, and the characteristics and the reliability of a semiconductor device are improved.

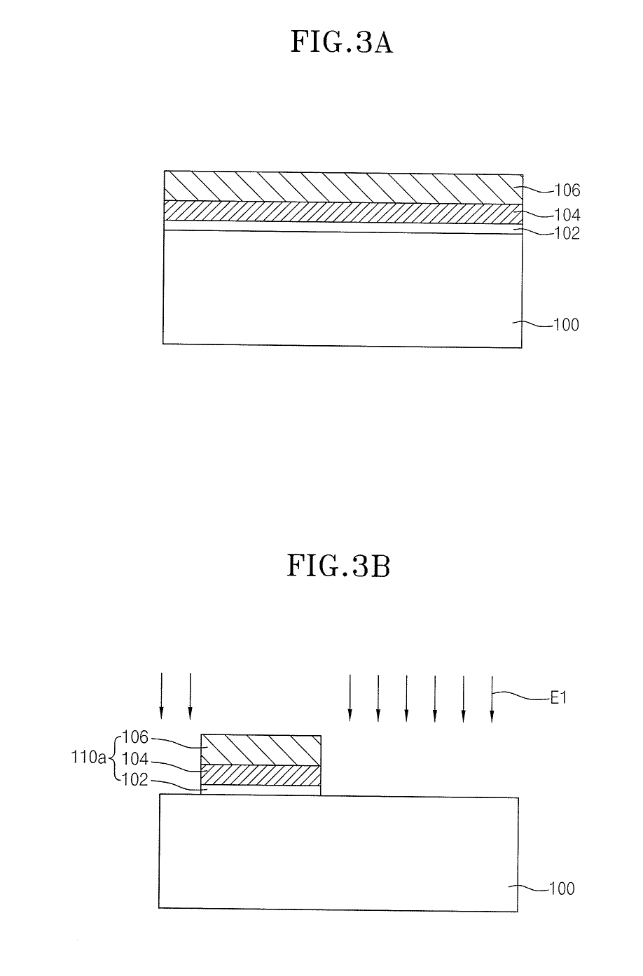

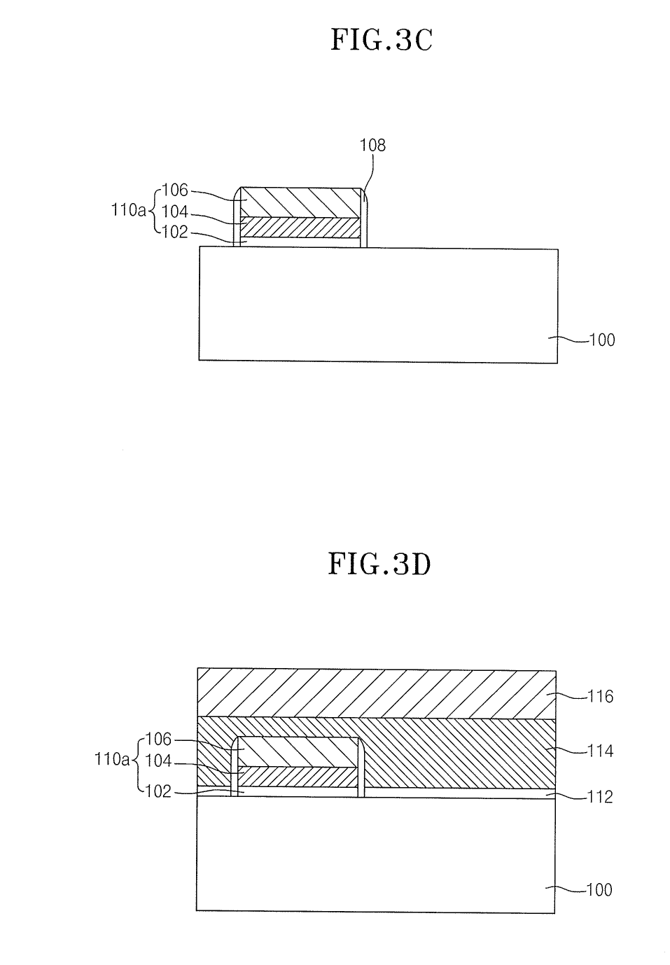

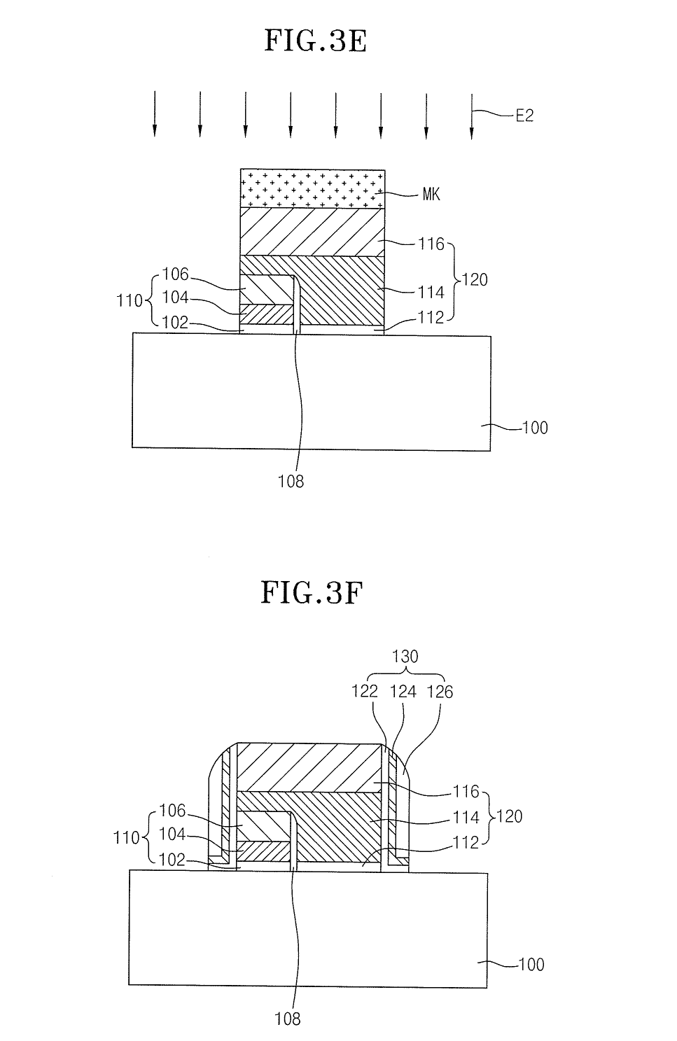

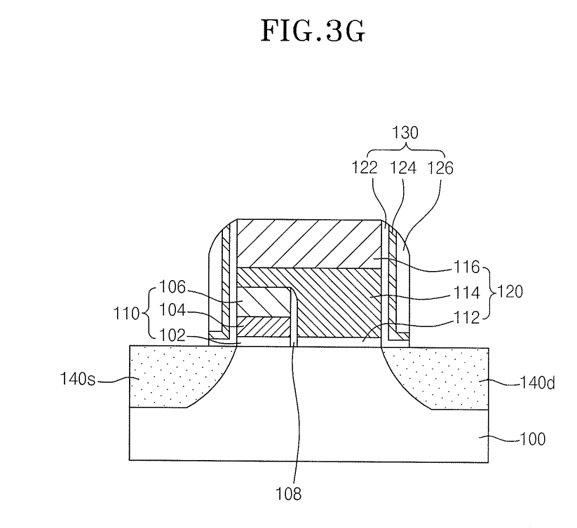

FIGS. 3A through 3G are cross-sectional views taken in correspondence with the line A-A′ of FIG. 1, shown for illustrating the processes of a method for manufacturing a semiconductor device in accordance with another embodiment of the present invention.

Referring to FIG. 3A, a first gate insulation layer 102, a first gate conductive layer 104, and a first gate hard mask layer 106 are sequentially formed on a semiconductor substrate 100. The first gate insulation layer 102 comprises, for example, an oxide layer, and the first gate conductive layer 104 comprises, for example, a stack of a doped polysilicon layer and a metal layer.

Referring to FIG. 3B, a conductive pattern 110a is formed on the semiconductor substrate 100 by conducting primary etching ‘E1’ on the first gate hard mask layer 106, the first gate conductive layer 104, and the first gate insulation layer 102.

Referring to FIG. 3C, first spacers 108 are formed on both side walls of the conductive pattern 110a. The first spacers 108 comprise, for example, a stack structure including an oxide layer and a nitride layer.

Referring to FIG. 3D, a second gate insulation layer 112 is formed on the semiconductor substrate 100 the first spacers 108 and the conductive pattern 110a formed thereon. Preferably, the second gate insulation layer 112 is formed as an oxide layer through a thermal oxidation process.

Then, a second gate conductive layer 114 is formed on the second gate insulation layer 112, and a planarization process is conducted on the second gate conductive layer 114. The second gate conductive layer 114 is formed as a stack of a doped polysilicon layer and a metal layer. According to an embodiment of the present invention, the doped polysilicon layer of the second gate conductive layer 114 may be the same as the doped polysilicon layer of the first gate conductive layer 104, or alternatively the doped polysilicon layer of the second gate conductive layer 114 may be doped with other impurities. Subsequently, a second gate hard mask layer 116 is formed on the second gate conductive layer 114 having the planarization process conducted thereon.

According to an embodiment of the present invention, in order to ensure that the planarization degree of the second gate hard mask layer 116 formed on the second gate conductive layer 114 is increased to some extent, it is preferred that the second gate conductive layer 114 be formed to completely cover the conductive pattern 110a. Through this, in the present invention, an additional planarization process can be omitted, whereby it is possible to reduce the manufacturing cost of a semiconductor device.

Referring to FIG. 3E, a mask pattern MK is formed on the second gate hard mask layer 116 to overlap with a portion of the conductive pattern 110a. For example, the mask pattern MK may be formed on the second gate hard mask layer 116 such that the mask pattern MK overlaps with a side end portion of the conductive pattern 110a including a first spacer 108 formed on the side of the conductive pattern 110a. Subsequently, a secondary etching ‘E2’ is conducted on the portions of the second gate hard mask layer 116, the second gate conductive layer 114, the second gate insulation layer 112, and the conductive pattern 110a using the mask pattern MK as an etch mask.

As a result of the secondary etching E2 of the second gate conductive layer 114, and the second gate insulation layer 112, a main gate 120 is formed and an internal gate 110 is formed within a portion of the main gate 120 due to the secondary etching E2 of the conductive pattern 110a. Here, the internal gate 110 is formed such that one side end thereof is flush with one side end of the main gate 120. That is, since one side end portion of the internal gate 110 and a corresponding one side end portion of the main gate 120 are defined through the same secondary etching E2, the one side end portion of the internal gate 110 and the corresponding one side end portion of the main gate 120 are substantially coplanar.

According to an embodiment of the present invention, the internal gate 110 is formed through a combination of the primary and secondary etchings ‘E1’ and ‘E2’. Accordingly, in the present invention, the internal gate 110 is formed to have a short channel length in comparison with the lithography margins of respective etching processes.

Referring to FIG. 3F, the mask pattern MK is removed, and second spacers 130 are formed both sidewalls of the main gate 120 and the sidewall of the one side end portion of the internal gate 110 defined through the secondary etching E2. According to an embodiment of the present invention, the second spacers 130 comprise, for example, a stack of a first oxide layer 122, a nitride layer 124, and a second oxide layer 126.

Referring to FIG. 3G, a source region 140s is formed in the surface of a portion of the semiconductor substrate 100 and a drain region 140d is formed in the surface of another portion of the semiconductor substrate 100. In detail, the source region 140s is formed in a portion of the semiconductor substrate 100 that adjoins the portion of the main gate 120 having the internal gate 110 formed therein, and the drain region 140d is formed in the surface of a portion of the semiconductor substrate 100 that adjoins the other side end of the main gate 120 opposite the side having the internal gate 110 formed therein.

Thereafter, while not shown in the drawings, first contacts, which contact the main gate 120, and a second contact, which contacts the internal gate 110 are formed, and by sequentially conducting a series of well-known subsequent processes, the manufacture of a semiconductor device according to the embodiment of the present invention is completed. According to an embodiment of the present invention, the first and second contacts may be simultaneously formed. Alternatively, the second contact may be formed after the first contacts are formed, or the first contacts may be formed after the second contact is formed.

As is apparent from the above description, in the present invention, when a main gate is turned off, a negative voltage can be selectively applied only to an internal gate, which adjoins a source region, through a second contact. Accordingly, in the present invention, since a difference in potential barrier between the source region and a channel can be sufficiently secured, a DIBL phenomenon can be prevented. Also, in the present invention, since a difference in voltage between the main gate and a drain region is decreased, a GIDL phenomenon can be prevented. Therefore, in the present invention, it is possible to avoid the DIBL phenomenon without undergoing the GIDL phenomenon. Consequently, according to embodiments of the present invention, the characteristics and the reliability of a semiconductor device can be improved because leakage current is reduced.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor device comprising:
a main gate formed on a semiconductor substrate;
a source region and a drain region formed in a surface of the semiconductor substrate on opposite sides of the main gate; and
an internal gate formed within a portion of the main gate adjoining the source region.

2. The semiconductor device according to claim 1, wherein the internal gate has spacers on opposite sidewalls thereof.

3. The semiconductor device according to claim 1, wherein the internal gate is formed such that a side end of the internal gate adjoining the source region is substantially coplanar with a side end of the main gate adjoining the source region.

4. The semiconductor device according to claim 1, further comprising:
one or more first contacts contacting the main gate; and
a second contact contacting the internal gate.

5. A method for manufacturing a semiconductor device, comprising:
forming a main gate on a semiconductor substrate and an internal gate within a portion of the main gate; and
forming a source region in a portion of a surface of the semiconductor substrate adjoining the portion of the main gate having the internal gate formed therein and forming a drain region in another portion of the surface of the semiconductor substrate adjoining a side end of the main gate opposite the portion of the main gate having the internal gate formed therein.

6. The method according to claim 5, wherein spacers are formed on opposite sidewalls of the internal gate.

7. The method according to claim 5, wherein the internal gate is formed such that a side end of the internal gate adjoining the source region is substantially coplanar with a side end of the main gate adjoining the source region.

8. The method according to claim 5, further comprising:
forming one or more first contacts contacting the main gate and a second contact contacting the internal gate after the forming the source region and the drain region.

9. A method for manufacturing a semiconductor device, comprising:
forming a conductive pattern on a semiconductor substrate;
forming a conductive layer on the semiconductor substrate having the conductive pattern formed thereon, wherein the conductive layer is formed to cover the conductive pattern;
forming a main gate by etching the conductive layer and an internal gate within a portion of the main gate by etching the conductive pattern; and
forming a source region in a portion of a surface of the semiconductor substrate adjoining the portion of the main gate having the internal gate formed therein and forming a drain region in another portion of the surface of the semiconductor substrate adjoining a side end of the main gate opposite the portion of the main gate having the internal gate formed therein.

10. The method according to claim 9, wherein forming the conductive pattern comprises:
forming a first gate insulation layer, a first gate conductive layer, and a first gate hard mask layer on the semiconductor substrate; and
etching the first gate hard mask layer, the first gate conductive layer, and the first gate insulation layer.

11. The method according to claim 9, wherein, further comprising:
forming spacers on opposite sidewalls of the conductive pattern after forming the conductive pattern and before forming the conductive layer.

12. The method according to claim 9, further comprising:
forming a second gate insulation layer on the semiconductor substrate having the conductive pattern formed therein after forming the conductive pattern and before forming the conductive layer.

13. The method according to claim 9, wherein the conductive layer comprises a second gate conductive layer for a main gate.

14. The method according to claim 9, further comprising:
conducting a planarization process for the conductive layer; and
forming a second hard mask layer for a main gate on the planarized conductive layer,
wherein the planarization process and the forming of the second hard mask are conducted after forming the conductive layer and before forming the main gate and the internal gate.

15. The method according to claim 9, wherein forming the main gate and the internal gate comprises:
forming a mask pattern on the conductive layer to overlap with a side end portion of the conductive pattern;
etching the conductive layer and the conductive pattern using the mask pattern as an etch mask; and
removing the mask pattern.

16. The method according to claim 9, wherein the internal gate is formed such that a side end of the internal gate adjoining the source region is substantially coplanar with a side end of the main gate adjoining the source region.

17. The method according to claim 9, further comprising:
forming one or more first contacts contacting the main gate and a second contact contacting the internal gate after forming the source region and the drain region.
